(19) United States
(12) Patent Application Publication
(10) Pub. No.: US 2007/0074743 A1
(43) Pub. Date: Apr. 5, 2007

(54) H2 conditioning of chamber following cleaning cycle

(76) Inventors: Graham McFarlane, Murrieta, CA (US); Richard Hogle, Oceanside, CA (US)

Correspondence Address: THE BOC GROUP, INC., 575 MOUNTAIN AVENUE, MURRAY HILL, NJ, 07974-2064, US

(21) Appl. No.: 11/242,683

(22) Filed: Oct. 4, 2005

(51) Int. Cl. B08B 9/00; C23C 16/00

(52) U.S. Cl. 134/22.1; 134/166 R; 118/723 R

(57) ABSTRACT

The present invention relates to methods and apparatus used in the cleaning of chambers, such as semiconductor processing chambers. In particular, fluorine from a fluorine generator is used in the cleaning cycle and by-product hydrogen from the fluorine generation is used to condition the chamber and remove residual fluorine following the cleaning cycle.

### FIELD OF THE INVENTION

The present invention relates to the field of fluorine plasma cleaning of chamber used for semiconductor device fabrication. More specifically, the present invention is directed to the efficient use of H₂ generated from a fluorine plasma cleaning system to condition a chamber following a cleaning cycle.

### BACKGROUND OF THE INVENTION

Semiconductor devices are typically produced in vacuum chambers using an appropriate series of batch process steps. These batch processing steps can be grouped into broad categories including film deposition, thin film oxidation, dopant addition, ion implantation, and plasma etching, among others; that are performed over a wide range of operating conditions. Specific processing step can combine characteristics from multiple broad process classifications to achieve specific process objectives.

For example, one of the primary steps in fabricating semiconductor devices is the formation of a dielectric layer on a semiconductor surface. Such dielectric layers can be deposited by chemical vapor deposition (CVD); such as a thermal CVD process, wherein reactive gases are supplied to the substrate surface where heat induced chemical reactions take place to produce the desired film. Alternatively, a plasma process can be used, wherein a controlled plasma is formed to decompose or energize reactive species to produce the desired film.

It is common for reaction by-products from these process steps to accumulate on the chamber walls, which can lead to manufacturing quality issues for subsequent batch processes, including wafer failure. Therefore, periodic chamber cleanings must be carried out after processing a certain number of batches, to insure quality and system performance standards are maintained. It is preferable to carry out the periodic chamber cleanings without breaking the chamber vacuum seal, although more complete preventive maintenance chamber cleaning that require system shut down may also be necessary. However, all of the cleanings cause process down time and impact the product manufacturing cycles. Providing an efficient, non-damaging cleaning of the chamber or substrate enhances performance of the devices produced.

The reduction of down time is a constant desire as higher processing efficiency results in lower processing cost. Increased processing efficiencies of as little as one or two percent can result in substantial accumulated cost savings over the lifetime of a processing facility. Providing an efficient, non-damaging cleaning of the chamber or substrate also enhances performance of the devices produced.

Fluorine based gases are often used to perform the chamber cleaning, but create by-product gases that requires abatement. The greater the volume of cleaning gas used, the greater the volume of by-product generated that requires abatement. This also results in increased cycle time and increased processing costs.

U.S. Pat. No. 6,347,636 discloses a method of cleaning residue from a wafer chamber using fluorine atoms, based on the reactivity of fluorine with the silicon dioxide residue. The preferred fluorine radical source disclosed is NF₃.

It is also known to use hydrogen (H₂) gas or plasma activated H₂ gas to remove fluorine residuals following the cleaning cycle. The H₂ may be treated as necessary and supplied to the chamber from an available source, such as an H₂ storage tank or cylinder.

U.S. Pat. No. 6,534,423 discloses a process of using inductively coupled hydrogen plasma to treat a chamber after a fluorine based chamber cleaning cycle. The hydrogen is provides from a separate cylinder or storage tank that must be purchased and connected to the plasma system. Fresh supplies of hydrogen must be continually supplied, adding to the overall cost of the system and processing.

Therefore, there remains a need for improvements in the field of chamber cleaning using fluorine based gases and hydrogen conditioning of the chambers.

### SUMMARY OF THE INVENTION

The present invention is directed to a system where the hydrogen required in a conditioning step is generated as a by-product of fluorine source gas generation. The present invention accesses an abundant supply of hydrogen that is available without additional system cost, thereby providing a significant improvement over the prior art systems that require separate purchase of gas; e.g. cylinder gas. The present invention also provides an integrated approach to the disposal or abatement of the co-generated hydrogen. The present invention is also directed to a system for treating a chamber with an H₂ stream following cleaning with fluorine plasma, to remove residual fluorine from the chamber.

The present invention further provides a method for cleaning a chamber. In particular, fluorine (F₂) from a fluorine generator is directed to flow from the generator to the chamber and thereby remove accumulated material from the interior of the chamber. The reactant gases are then vented from the system through a vacuum pump as the cleaning process proceeds. The generation of F₂ also results in the creation of H₂ as a by-product and the method of the present invention further directs a flow of the by-product H₂ to the chamber interior. The H₂ reacts with substantially all of the fluorine remaining in the reaction chamber to product HF and the HF is then removed from the reaction chamber. The generated F₂ and H₂ may be advantageously stored in separate storage chambers or tanks, so as to be ready to use when needed for the cleaning and treatment process.

The present invention provides an apparatus for removing residual fluorine from a chamber, such as a reaction chamber, wherein the chamber is connected to a fluorine generator, such as an electrolytic fluorine generator, for producing an F₂ component and an H₂ by-product component. The generator may have first and second generator outlets, with the first generator outlet in communication with an inlet of the chamber for directing the F₂ component into the chamber. The second generator outlet also communicates with the inlet of the chamber and directs the H₂ by-product to the chamber. In a further embodiment of the present invention, an H₂ storage tank is provided between the second generator outlet and the chamber inlet. An F₂ storage tank may also be included in the apparatus, located between the first generator outlet and the chamber inlet.

### BRIEF DESCRIPTION OF THE DRAWINGS

FIG. 1 is a schematic representation of one embodiment of the present invention.

### DETAILED DESCRIPTION OF THE INVENTION

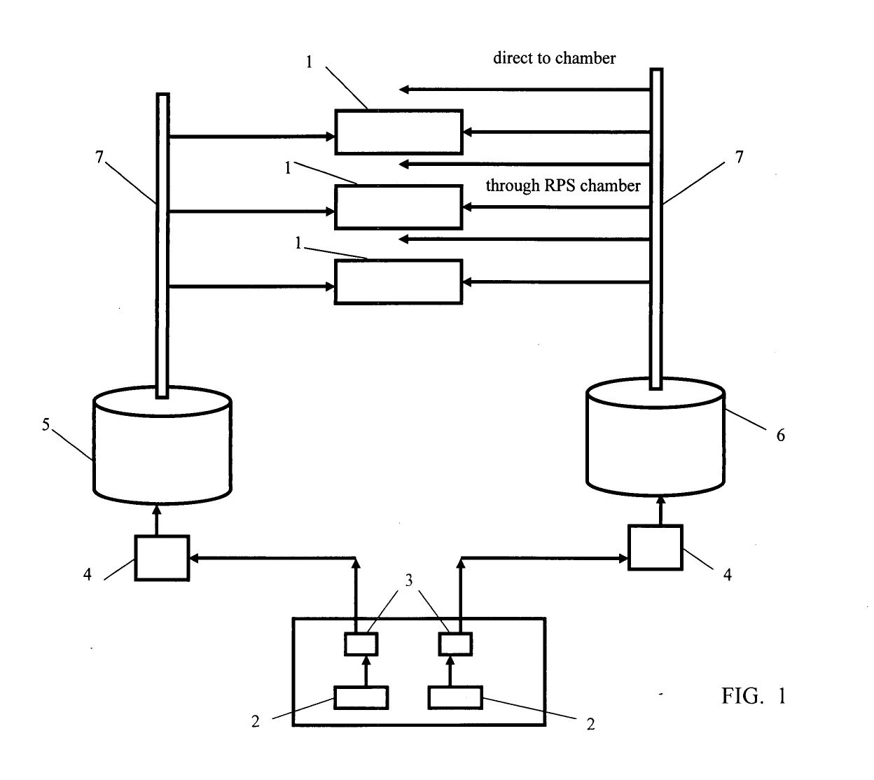

One embodiment of the present invention is shown in FIG. 1, wherein a remote plasma system 1 for each tool is connected with F₂ and H₂ sources. The F₂ is sourced from F₂ electrolytic cells 2 that generate F₂ and also generate H₂ and HF as by-products. The generated gases are directed to means 3, such as NaF beds, to remove the HF, the means 3 preferably located proximate to the cells 2. Optionally, the resulting gases pass through compressors 4 to increase the storage capacity of the F₂ storage tank 5 and the H₂ storage tank 6. The compressors 4 may further provide the pressure needed to enable the process. Enough F₂ sufficient to meet the sporadic F₂ demand rates balanced against the production rates, may be stored in the F₂ storage tank 5. Similarly, the H₂ may be stored in the H₂ storage tank 6. The gases are delivered from the storage tanks 5 and 6, respectively, to the remote plasma systems 1 via a network of manifolds 7.

The F₂ is directed to the remote plasma systems 1 to be used in removing impurities from the chamber walls during the chamber cleaning process. Upon completion of the chamber cleaning cycle, residual amounts of F₂ may remain in the chamber. To remove this residual F₂, H₂ is released from the H₂ storage tank 6 to react with the residual F₂ and form HF. The H₂ may be directed either through the remote plasma systems 1 to activate the H₂ to hydrogen radicals or may be supplied directly to the chamber. Either the hydrogen radicals or diatomic H₂ molecules react with the residual F₂ atoms and form HF. The HF formed is very volatile at the chamber operating conditions, from 0.1 Torr to about 100 Torr and therefore is quickly destroyed. The H₂ conditioning step is shorter than the cleaning cycle by a factor of 5 to 10 and therefore allows nearly immediate processing to continue. In other words, virtually no system down time is required.

Significant advantages are realized by using the processes and apparatus of the present invention. For example, by using the H₂ created as a by-product of the fluorine generation, the need for additional hydrogen sources and delivery systems are eliminated. In addition, the need to dispose or abate by-product H₂ from the fluorine generation is unnecessary, because such H₂ is put to a useful purpose. Further, by reacting the residual fluorine and fluorine containing compounds from the chamber cleaning cycle, a significantly reduces volume of F₂ must be abated.

In addition, the use of F₂ is desirable in many chip manufacturing processes, other than chamber cleaning, because of the significantly increased etch rates that can be obtained by using higher pressures of the remote plasma systems possible with F₂, as compared to the use of other fluorine based compounds, for example NF₃. However, use of F₂ for these processes results in more residual fluorine in the chamber, that can adversely affect subsequent wafer manufacture. This additional residual F₂ can be converted to HF using by-product H₂ in the same way as noted above. In this way, the by-product H₂ is also consumed and expensive abatement equipment designed to remove the residual F₂ and potentially reactive H₂ from the system is unnecessary.

The present invention allows the F₂ generator to be used to its full potential, as both the F₂ and H₂ by-products are usefully employed. The present invention provides a highly efficient manufacturing process for F₂ and H₂ and for highly efficient chamber cleaning, with reduced system cost and downtime and increased overall wafer output.

Cleaning cycle times vary widely, depending on the deposition process conditions; chamber size, acceptable particle contamination levels, etc. By using the readily available by-product H₂ from the fluorine generator, the chamber can be better and more rapidly prepared for the next round of deposition. In addition, the use of hydrogen conditioning, reduces the occurrence of flaking on the first product wafers run after cleaning cycles. Moreover, the walls of the chamber that have been conditioned with hydrogen can accumulate more deposition impurities without contaminating the wafers, thereby resulting in longer total productive process cycles between cleaning cycles. This further reduces the cost of operation.

The present invention provides all of the above advantages using a by-product produced by the fluorine generator and using the same remote plasma systems used for the cleaning process, thereby avoiding additional operating costs for extra equipment and purchased hydrogen.

The following examples describe the present invention in greater detail.

### EXAMPLE 1

This example relates to typical deposition process for a batch of four silicon oxide doped wafers. Following chamber cleaning without hydrogen conditioning, flaking generally occurs. In accordance with the present invention, following a normal cleaning cycle, a 30 second pure hydrogen flow was followed by a 210 second hydrogen flow with the remote plasma system turned on. There was no flaking observed on the subsequent thirty wafers processed after the hydrogen conditioning of the chamber.

### EXAMPLE 2

A typical cleaning cycle uses a flow of F₂ to the chamber at 6 slpm for 300 seconds, for a total of 30 liters of F₂ used. According to the present invention, following the cleaning cycle, non-activated H₂ was provided to the chamber at 40 slpm for 30 seconds and then the remote plasma system was turned on the H₂ was provided at 20 slpm for 30 seconds. Wafer processing was then resumed. The by-product H₂ products in making the 30 liters of F₂ used in the cleaning cycle was consumed in the hydrogen conditioning process. Therefore, no H₂ abatement was required and there was no additional cost for the H₂ used in the conditioning process.

It is anticipated that other embodiments and variations of the present invention will become readily apparent to the skilled artisan in the light of the foregoing description and examples, and it is intended that such embodiments and variations likewise be included within the scope of the invention as set out in the appended claims.

1. A method for cleaning a chamber comprising:
creating fluorine and by-product hydrogen from a fluorine generator;
directing a flow of fluorine from the fluorine generator to a chamber to be cleaned;
cleaning the chamber using the fluorine;
directing a flow of by-product hydrogen to the chamber;
reacting residual fluorine remaining in the chamber with the hydrogen to produce hydrogen fluoride; and
removing the hydrogen fluoride from the chamber.

2. The method of claim 1 wherein the fluorine generator is an electrolytic fluorine generator.

3. The method of claim 1 wherein the fluorine and hydrogen are generated simultaneously by the fluorine generator.

4. The method of claim 1 further comprising:
storing the fluorine in a fluorine storage tank prior to the step of directing the fluorine to the chamber; and
and storing the hydrogen in a hydrogen storage tank prior to the step of directing the hydrogen to the chamber.

5. The method of claim 4 further comprising:
directing a predetermined amount of fluorine from the fluorine storage tank to the chamber; and
directing a predetermined amount of hydrogen from the hydrogen storage tank to the chamber.

6. The method of claim 1 wherein the chamber is a semiconductor processing chamber.

7. The method of claim 1 wherein the fluorine is F₂ and the hydrogen is H₂.

8. An apparatus for cleaning a chamber comprising:
a chamber to be cleaned;
a fluorine generator for producing fluorine and by-product hydrogen; and
communication means between the chamber and the fluorine generator for directing the fluorine to the chamber and for directing the hydrogen to the chamber.

9. The apparatus of claim 8 further comprising a hydrogen storage tank located between and communicating with the fluorine generator and the chamber for storing the hydrogen until needed by the chamber.

10. The apparatus of claim 8 further comprising a fluorine storage tank located between and communicating with the fluorine generator and the chamber for storing the fluorine until needed by the chamber.

11. The apparatus of claim 8 wherein the fluorine generator is an electrolytic fluorine generator.

12. The apparatus of claim 8 wherein the communication means comprises:
a first generator outlet communicating with an inlet to the chamber for directing the fluorine to the chamber; and
a second generator outlet communicating with the inlet to the chamber for directing the hydrogen to the chamber.

13. The apparatus of claim 8 wherein the chamber is a semiconductor processing chamber.

14. A method for removing residual fluorine from a chamber comprising:
creating by-product hydrogen from a fluorine generator;
directing a flow of by-product hydrogen to the chamber;
reacting the residual fluorine with the hydrogen to produce hydrogen fluoride; and
removing the hydrogen fluoride from the chamber.

15. The method of claim 14 wherein the fluorine generator is an electrolytic fluorine generator.

16. The method of claim 14 further comprising:
storing the hydrogen in a hydrogen storage tank prior to the step of directing the hydrogen to the chamber.

17. The method of claim 16 further comprising:
directing a predetermined amount of hydrogen from the hydrogen storage tank to the chamber.

18. The method of claim 14 wherein the chamber is a semiconductor processing chamber.

19. An apparatus for removing residual fluorine from a chamber comprising:
a chamber containing residual fluorine;
a fluorine generator for producing by-product hydrogen; and
communication means between the chamber and the fluorine generator for directing the hydrogen to the chamber.

20. The apparatus of claim 19 further comprising a hydrogen storage tank located between and communicating with the fluorine generator and the chamber for storing the hydrogen until needed by the chamber.

21. The apparatus of claim 19 wherein the fluorine generator is an electrolytic fluorine generator.

22. The apparatus of claim 19 wherein the communication means comprises:
a generator outlet communicating with an inlet to the chamber for directing the hydrogen to the chamber.

23. The apparatus of claim 19 wherein the chamber is a semiconductor processing chamber.
